(19) United States
(12) Patent Application Publication
(10) Pub. No.: US 2025/0192783 A1
(43) Pub. Date: Jun. 12, 2025

(54) INTERFACE CIRCUITS, NON-VOLATILE MEMORY DEVICES, AND MEMORY CONTROLLERS HAVING ENHANCED OUTPUT DRIVERS THEREIN

(71) Applicant: Samsung Electronics Co., Ltd., Suwon-si (KR)

(72) Inventors: Yeonwook Jung, Suwon-si (KR); Sejin Baek, Suwon-si (KR); Jungmin Seo, Suwon-si (KR); Gyosoo Choo, Suwon-si (KR)

(21) Appl. No.: 18/789,762

(22) Filed: Jul. 31, 2024

(30) Foreign Application Priority Data
Dec. 12, 2023 (KR) 10-2023-0180105

(51) Int. Cl. H03K 19/0185; G06F 3/06; G11C 16/32

(52) U.S. Cl. CPC H03K 19/018521; G06F 3/0604; G06F 3/0659; G06F 3/0679; G11C 16/32

(57) ABSTRACT

An output driver includes: a selection circuit configured to selectively output either a first pull-up driving signal or a pulse signal, in response to a received first control signal, a first pull-up driver circuit configured to provide a first supply voltage to a first node electrically connected to a data pin, in response to the first pull-up driving signal or the pulse signal received from the selection circuit, a second pull-up driver circuit configured to provide a second supply voltage having a second level, which is less than or equal to a first level of the first supply voltage, to the first node, in response to a second pull-up driving signal, a first decoupling capacitor, and a capacitance optimization circuit configured to change a capacitance of a decoupling capacitor having a first terminal electrically connected to a third node to which the first supply voltage is applied.

### REFERENCE TO PRIORITY APPLICATION

This application claims priority under 35 U.S.C. § 119 to Korean Patent Application No. 10-2023-0180105, filed Dec. 12, 2023, the disclosure of which is hereby incorporated herein by reference.

### BACKGROUND

The inventive concept relates to electronic devices and, more specifically, to output driver circuits for integrated circuits including memory devices and memory controllers.

Memory devices are used to store data and are typically classified into volatile memory devices and non-volatile memory devices. As an example of a non-volatile memory device, a flash memory device may be used in cell phones, digital cameras, portable digital assistants (PDAs), portable computer devices, stationary computer devices, and other devices. In a non-volatile memory device, an output driver that outputs a data signal may include a pull-up driver and a pull-down driver each including a plurality of transistors.

### SUMMARY

The inventive concept provides an output driver to strengthen a power integrity (PI) and a signal integrity (SI) of the output driver, an interface circuit, a non-volatile memory device, and a memory controller.

According to an aspect of the inventive concept, an output driver is provided that includes: a selection circuit configured to output either a first pull-up driving signal or a pulse signal according to a first control signal, a first pull-up driver circuit configured to transmit a first supply voltage to a first node connected to a data pin based on the first pull-up driving signal or the pulse signal of the selection circuit, a second pull-up driver circuit configured to transmit a second supply voltage having a second level lower than a first level of the first supply voltage to the first node based on a second pull-up driving signal, a first decoupling capacitor connected to a second node to which the second supply voltage is applied and a line to which a third supply voltage of a third level lower than the first level and the second level is applied, a capacitance optimization circuit configured to change a capacitance of a decoupling capacitor between a third node to which the first supply voltage is applied and the line to the first capacitance or more, based on a second control signal, and a pull-down driver circuit configured to transmit the third supply voltage to the first node based on a pull-down driving signal.

According to another aspect of the inventive concept, a non-volatile memory device is provided, which includes: a memory cell array, a control logic circuit configured to output a plurality of control signals based on a command signal, and a data input/output circuit configured to generate a plurality of driving signals that are based on internal data and a clock signal output from the memory cell array, and output data that is based on the plurality of control signals and the plurality of driving signals. The data input/output circuit includes a multiplexer configured to output either a first pull-up driving signal or a pulse signal according to a first control signal, a first pull-up driver including a first electrode connected to a third node to which a first supply voltage is applied, a second electrode connected to a first node connected to a data pin, and a gate electrode to which the first pull-up driving signal or the pulse signal is applied, a second pull-up driver including a first electrode connected to a second node to which a second supply voltage having a second level lower than the first level of the first supply voltage is applied, a second electrode connected to the first node, and a gate electrode to which a second pull-up driving signal is applied, a first decoupling capacitor connected to a line to which a third supply voltage of a third level lower than the first level and the second level is applied and the second node, a second decoupling capacitor connected to the third node and the line, a third decoupling capacitor connected to a fourth node and the line, a switch configured to connect the third node to the fourth node or electrically open the third node and the fourth node according to a second control signal, a pull-down driver including a first electrode connected to the first node, a second electrode connected to the line, and a gate electrode to which a pull-down driving signal is applied, and an equalizer configured to output the pulse signal based on a sixth control signal.

According to another aspect of the inventive concept, a memory controller is provided that includes a processor configured to receive data and a command signal, output a plurality of control signals based on the command signal, and output a clock signal and the data, and a memory interface circuit configured to generate a plurality of driving signals based on the data and the clock signal, and output internal data based on the plurality of control signals and the plurality of driving signals. The memory interface circuit includes a multiplexer configured to output either a first pull-up driving signal or a pulse signal according to a first control signal, a first pull-up driver including a first electrode connected to a third node to which a first supply voltage is applied, a second electrode connected to a first node connected to a data pin, and a gate electrode to which the first pull-up driving signal or the pulse signal is applied, a second pull-up driver including a first electrode connected to a second node to which a second supply voltage having a second level lower than the first level of the first supply voltage is applied, a second electrode connected to the first node, and a gate electrode to which a second pull-up driving signal is applied, a first decoupling capacitor connected to a line to which a third supply voltage of a third level lower than the first level and the second level is applied and the second node, a second decoupling capacitor connected to the third node and the line, a third decoupling capacitor connected to a fourth node and the line, a switch configured to connect the third node to the fourth node or electrically open the third node and the fourth node according to a second control signal, a pull-down driver including a first electrode connected to the first node, a second electrode connected to the line, and a gate electrode to which a pull-down driving signal is applied, and an equalizer configured to output the pulse signal based on a sixth control signal.

According to another aspect of the inventive concept, an interface circuit is provided that includes a pre-driver circuit configured to output a plurality of driving signals based on internal data and a clock signal, and an output driver circuit configured to output data based on a plurality of control signals received and the plurality of driving signals. The output driver circuit includes a multiplexer configured to output either a first pull-up driving signal or a pulse signal according to a first control signal, a first pull-up driver including a first electrode connected to a third node to which a first supply voltage is applied, a second electrode connected to a first node connected to a data pin, and a gate electrode to which the first pull-up driving signal or the pulse signal is applied, a second pull-up driver including a first electrode connected to a second node to which a second supply voltage having a second level lower than the first level of the first supply voltage is applied, a second electrode connected to the first node, and a gate electrode to which a second pull-up driving signal is applied, a first decoupling capacitor connected to a line to which a third supply voltage of a third level lower than the first level and the second level is applied and the second node, a second decoupling capacitor connected to the third node and the line, a third decoupling capacitor connected to a fourth node and the line, a switch configured to connect the third node to the fourth node or electrically open the third node and the fourth node according to a second control signal, a pull-down driver including a first electrode connected to the first node, a second electrode connected to the line, and a gate electrode to which a pull-down driving signal is applied, and an equalizer configured to output the pulse signal based on a sixth control signal.

### BRIEF DESCRIPTION OF THE DRAWINGS

Embodiments will be more clearly understood from the following detailed description taken in conjunction with the accompanying drawings in which:

FIG. 1 is a diagram showing an output driver according to an embodiment;

FIG. 2 is a diagram showing a capacitance optimization circuit according to an embodiment;

FIG. 3 is a circuit diagram of an output driver according to an embodiment;

FIGS. 4 and 5 are diagrams for explaining first and second terminations of the output driver of FIG. 3;

FIG. 6 is a diagram for explaining a third termination of the output driver of FIG. 3;

FIG. 7 is a circuit diagram of an output driver according to an embodiment;

FIG. 8 is a diagram for explaining first and second terminations of the output driver of FIG. 7;

FIG. 9 is a diagram for explaining a third termination of the output driver of FIG. 7;

FIG. 10 is a circuit diagram of an output driver according to an embodiment;

FIG. 11 is a diagram for explaining a first termination of the output driver of FIG. 10;

FIG. 12 is a diagram for explaining a second termination of the output driver of FIG. 10;

FIG. 13 is a diagram for explaining a third termination of the output driver of FIG. 10;

FIG. 14 is a circuit diagram of an output driver according to an embodiment;

FIG. 15 is a diagram showing an output driver according to an embodiment;

FIG. 16 is a block diagram of an interface circuit according to an embodiment;

FIG. 17 is a diagram of a non-volatile memory, according to an embodiment;

FIG. 18 is a block diagram of a storage system, according to an embodiment; and

FIG. 19 is a block diagram illustrating at least a portion of an electronic system according to embodiments.

### DETAILED DESCRIPTION OF THE EMBODIMENTS

Hereinafter, embodiments of the inventive concept will be described in detail with reference to the attached drawings.

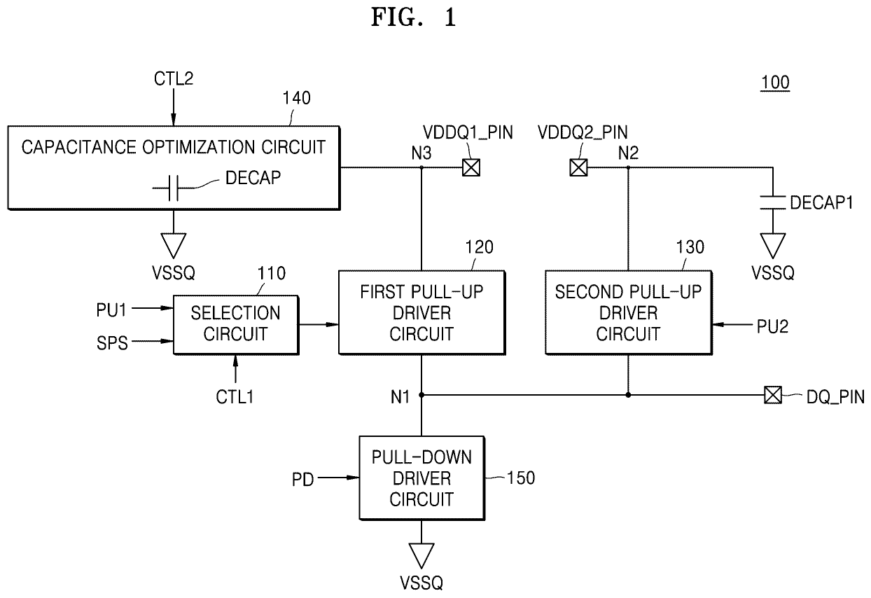

FIG. 1 is a diagram showing an output driver 100 according to an embodiment, which may include a selection circuit 110, a first pull-up driver circuit 120, a second pull-up driver circuit 130, a first decoupling capacitor DECAP1, a capacitance optimization circuit 140, and a pull-down driver circuit 150.

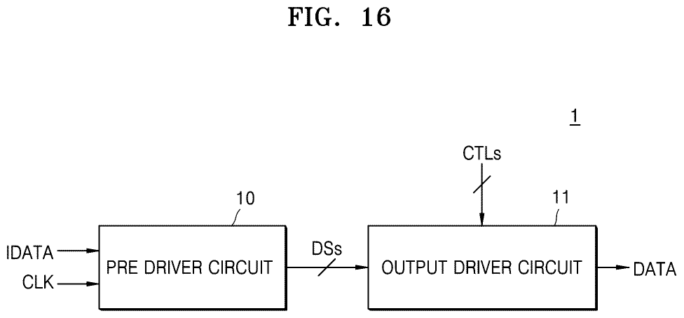

The selection circuit 110 may receive a first pull-up driving signal PU1 and a pulse signal SPS, and may perform a selection operation to output either the first pull-up driving signal PU1 or the pulse signal SPS according to a received first control signal CTL1. The first pull-up driving signal PU1 may be generated and output by an external pre-driver. The pre-driver (or pre-driver circuit) will be described below with reference to FIG. 16. The pulse signal SPS is a signal with a pulse width and may be generated and output by an equalization circuit. The equalization circuit may be included in the output driver 100 or may be provided external to the output driver 100. The first control signal CTL1 may be generated and output by external control logic.

The first pull-up driver circuit 120 may transmit a first supply voltage VDDQ1 to a first node N1 based on the first pull-up driving signal PU1 or the pulse signal SPS selected by the selection circuit 110. The first node N1 may be a node connected to a data pin DQ PIN. Data may be output to the outside through the data pin DQ PIN. The first supply voltage VDDQ1 may also be supplied to the output driver 100 through a first supply voltage pin VDDQ1_PIN. The ‘pin’ of the inventive concept may also be referred to as a ‘pad’. The first supply voltage VDDQ1 may be a supply voltage defined in a memory standard such as JEDEC Standard (JESD) and Open NAND Flash Interface (ONFI). For example, a first level of the first supply voltage VDDQ1 may be a constant 1.2 [V] in some embodiments. The first supply voltage VDDQ1 may be used as each of a channel voltage required to perform data communication between the output driver 100 and the outside, and an on-chip voltage required to operate a semiconductor chip including the output driver 100.

The second pull-up driver circuit 130 may transmit a second supply voltage VDDQ2 to the first node N1 based on a second pull-up driving signal PU2. The second pull-up driving signal PU2 may be generated and output by the external pre-driver. The second supply voltage VDDQ2 may also be supplied to the output driver 100 through a second supply voltage pin VDDQ2_PIN. The second supply voltage VDDQ2 may be a supply voltage defined in the memory standard. In an embodiment, the second supply voltage VDDQ2 may have a second level that is the same or lower than the first level of the first supply voltage VDDQ1. For example, the second level of the second supply voltage VDDQ2 may be a constant 1.2 [V] that is the same as the first level of the first supply voltage VDDQ1. Alternatively, the second level of the second supply voltage VDDQ2 may be 0.6 [V], which is lower than the first level of the first supply voltage VDDQ1. However, the embodiment is not limited thereto. The second level of the second supply voltage VDDQ2 may change according to a termination corresponding to an interface method. For example, the termination may include a Low Tapped Termination (LTT), a Center Tapped Termination (CTT), a Power Isolated Low Tapped Termination (PI-LTT), etc. defined in the memory standard. In the LTT and the CTT, the first level and the second level may both be 1.2 [V], and in the PI-LTT, the first level may be 1.2 [V] and the second level may be 0.6 [V]. However, the embodiment is not limited thereto. The second supply voltage VDDQ2 may be used as a channel voltage required to perform data communication between the output driver 100 and the outside.

Among a plurality of terminations supportable by the output driver 100, the current termination may be determined based on a command signal input from the outside. In an embodiment, among the LTT, the CTT, and the PI-LTT, the PI-LTT may be the default, but is not limited thereto. In case of power consumption, the PI-LTT consumes the least, the LTT consumes more power than the PI-LTT, and the CTT consumes more power than the PI-LTT and the LTT. On the other hand, in case of signal transmission capabilities such as a signal-to-noise ratio (SNR), the PI-LTT is the worst, the LTT is better than the PI-LTT, and the CTT is better than the PI-LTT and the LTT.

The first decoupling capacitor DECAP1 may perform a function of assisting a power integrity (PI) with respect to each of the plurality of terminations. The first decoupling capacitor DECAP1 may be connected to a second node N2 and a line to which a third supply voltage VSSQ is applied. The second node N2 may be connected to the second supply voltage pin VDDQ2_PIN, and the second supply voltage VDDQ2 may be applied to the second node N2. The third supply voltage VSSQ may be a supply voltage defined in the memory standard. In an embodiment, the third supply voltage VSSQ may have a third level, and the third level may be lower than the first level of the first supply voltage VDDQ1 and also lower than the second level of the second supply voltage VDDQ2. For example, the third supply voltage VSSQ may correspond to ground, and the third level of the third supply voltage VSSQ may be 0 [V]. However, the embodiment is not limited thereto. The third supply voltage VSSQ may be constant. The third supply voltage VSSQ may be used as a channel voltage required to perform data communication between the output driver 100 and the outside. The first decoupling capacitor DECAP1 may have a first capacitance. A capacitance may be proportional to the area of a decoupling capacitor (e.g. the decoupling capacitor DECAP or the first decoupling capacitor DECAP1). In an embodiment, the first capacitance may correspond to the size of the second pull-up driver circuit 130.

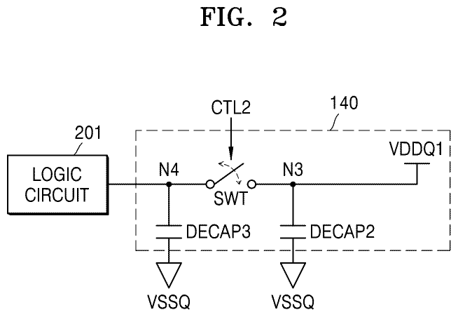

The capacitance optimization circuit 140 may change the capacitance of the decoupling capacitor DECAP included therein to the first capacitance or more based on a second control signal CTL2. The second control signal CTL2 may be generated and output by control logic. The decoupling capacitor DECAP may perform the function of assisting the PI with respect to some terminations and an on-chip area. The decoupling capacitor DECAP may be connected between the line to which the third supply voltage VSSQ is supplied and a third node N3. The third node N3 may be connected to the first supply voltage pin VDDQ1_PIN, and the first supply voltage VDDQ may be applied to the third node N3. An embodiment of the capacitance optimization circuit 140 is described more fully hereinbelow with reference to FIG. 2. The pull-down driver circuit 150 may transmit the third supply voltage VSSQ to the first node N1 based on the pull-down driving signal PD.

According to the above-described embodiments, the decoupling capacitor DECAP included in the capacitance optimization circuit 140 is optimized and channel equalization is implemented using the pulse signal SPS, and thus, the PI and a signal integrity (SI) with respect to the output driver 100 can be more robust. In addition, according to the above-described embodiments, a plurality of pull-up drivers are designed such that the first supply voltage VDDQ1 and the second supply voltage VDDQ2 are respectively applied, and the decoupling capacitor (e.g. the decoupling capacitor DECAP or the first decoupling capacitor DECAP1), which has the capacitance required by each of the pull-up drivers, is designed according to a termination, and thus, the PI and the SI with respect to the output driver 100 and the degree of integration of the output driver 100 are improved.

FIG. 2 is a diagram showing the capacitance optimization circuit 140 according to an embodiment. Referring to FIGS. 1 and 2, the capacitance optimization circuit 140 may include a second decoupling capacitor DECAP2, a third decoupling capacitor DECAP3, and a switch SWT. The second decoupling capacitor DECAP2 may be connected to a line to which the third supply voltage VSSQ is supplied and the third node N3. In an embodiment, the second decoupling capacitor DECAP2 may include a first terminal connected to the third node N3 and a second terminal connected to the line to which the third supply voltage VSSQ is supplied. The first supply voltage VDDQ1 may be applied to the third node N3, as shown.

According to some embodiments, the second decoupling capacitor DECAP2 may have a second capacitance. The second capacitance may have a capacity that is sufficient to support a channel voltage required to communicate data through a data pin DQ_PIN. The second capacitance may be greater than or equal to a first capacitance of the first decoupling capacitor DECAP1. In an embodiment, the second capacitance may correspond to the size of the first pull-up driver circuit 120, and the first capacitance may correspond to the size of the second pull-up driver circuit 130. For example, when the size of the first pull-up driver circuit 120 is larger than the size of the second pull-up driver circuit 130, the second capacitance may be greater than the first capacitance. And, when the size of the first pull-up driver circuit 120 is the same as the size of the second pull-up driver circuit 130, the second capacitance may be equal to the first capacitance.

The third decoupling capacitor DECAP3 may be connected to the line to which the third supply voltage VSSQ is supplied and a fourth node N4. In an embodiment, the third decoupling capacitor DECAP3 may include a first terminal connected to the fourth node N4 and a second terminal connected to the line to which the third supply voltage VSSQ is supplied. A logic circuit 201 may be connected to the fourth node N4. The logic circuit 201 may be a circuit configured to perform various functions included in the output driver 100 and/or disposed outside the output driver 100 in a semiconductor chip including the output driver 100 to perform various functions. The third decoupling capacitor DECAP3 may have a third capacitance. The third capacitance may be a capacity required for an on-chip region.

The switch SWT may selectively connect the third node N3 to the fourth node N4 based on the second control signal CTL2. When the third node N3 and the fourth node N4 are connected to each other, the second decoupling capacitor DECAP2 and the third decoupling capacitor DECAP3 may be connected in parallel. At this time, a composite capacitance of the second decoupling capacitor DECAP2 and the third decoupling capacitor DECAP3 connected in parallel may be the sum of the second capacitance and the third capacitance. The third node N3 and the fourth node N4 may also be electrically open. In an embodiment, the switch SWT may be implemented as a transistor such as a MOSFET, a transmission gate, or a Bipolar Junction Transistor (BJT), but is not limited thereto.

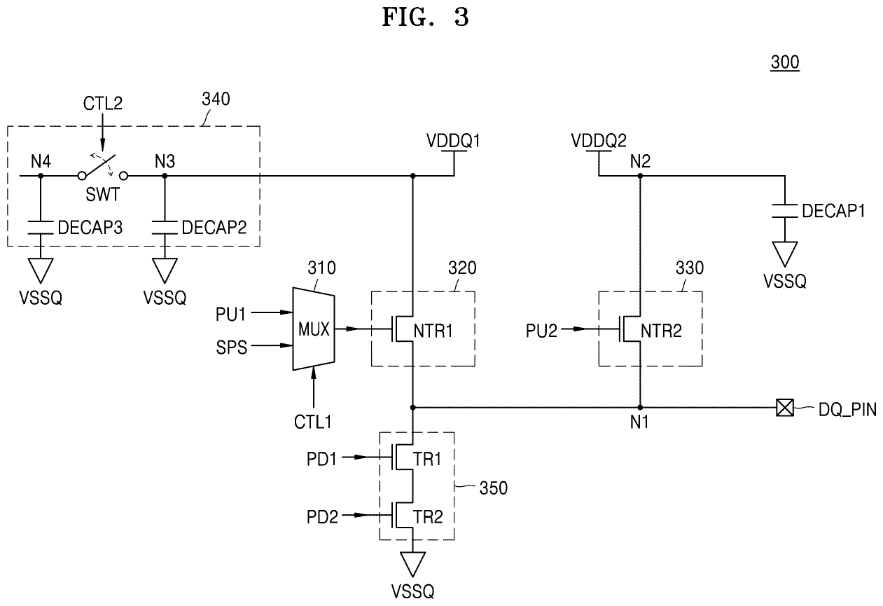

FIG. 3 is a detailed circuit diagram of an output driver 300 according to an embodiment. Referring to FIG. 3, the output driver 300 may include a selection circuit 310, a first pull-up driver circuit 320, a second pull-up driver circuit 330, the first decoupling capacitor DECAP1, a capacitance optimization circuit 340, and a pull-down driver circuit 350. The selection circuit 310 may be implemented as a 2-to-1 multiplexer; the multiplexer may output the first pull-up driving signal PU1 or the pulse signal SPS to the first pull-up driver circuit 320 according to a value of the first control signal CTL1.

The first pull-up driver circuit 320 may include a first N-type transistor NTR1. The first N-type transistor NTR1 may include a first electrode (i.e., a first current carrying terminal), a second electrode (i.e., a second current carrying terminal), and a gate electrode. The first electrode of the first N-type transistor NTR1 may be connected to the third node N3, and the first supply voltage VDDQ1 may be applied to the first electrode of the first N-type transistor NTR1. The second electrode of the first N-type transistor NTR1 may be connected to the first node N1. The first pull-up driving signal PU1 or the pulse signal SPS output from the selection circuit 310 may be applied to the gate electrode of the first N-type transistor NTR1. When the first pull-up driving signal PU1 or the pulse signal SPS output from the selection circuit 310 has a turn-on level, the first N-type transistor NTR1 may be turned on, and the first node N1 and the third node N3 may be electrically connected to each other. When the first pull-up driving signal PU1 or the pulse signal SPS output from the selection circuit 310 has a turn-off level, the first N-type transistor NTR1 may be turned off, and the first node N1 and the third node N3 may be electrically open from each other.

The second pull-up driver circuit 330 may include a second N-type transistor NTR2. The second N-type transistor NTR2 may include a first electrode (i.e., a first current carrying terminal), a second electrode (i.e., a second current carrying terminal), and a gate electrode. The first electrode of the second N-type transistor NTR2 may be connected to the second node N2, the second supply voltage VDDQ2 may be applied to the first electrode of the second N-type transistor NTR2, and the first electrode of the second N-type transistor NTR2 may be connected to the second node N2. The second electrode of the second N-type transistor NTR2 may be connected to the first node N1. The second pull-up driving signal PU2 may be input to the gate electrode of the second N-type transistor NTR2. When the second pull-up driving signal PU2 has a turn-on level, the second N-type transistor NTR2 may be turned on, and the first node N1 and the second node N2 may be electrically connected to each other. When the second pull-up driving signal PU2 has a turn-off level, the second N-type transistor NTR2 may be turned off, and the first node N1 and the second node N2 may be electrically open from each other. The second N-type transistor NTR2 may be referred to as a second pull-up driver. A transistor included in each of the first pull-up driver circuit 320 and the second pull-up driver circuit 330 may be referred to as a pull-up driver.

As described above with reference to FIG. 2, the capacitance optimization circuit 340 may include the second decoupling capacitor DECAP2, the third decoupling capacitor DECAP3, and the switch SWT. The pull-down driver circuit 350 may include a first transistor TR1 and a second transistor TR2. The first transistor TR1 and the second transistor TR2 may be electrically connected in series, as shown. A first pull-down driving signal PD1 may be input to a gate electrode of the first transistor TR1, and a second pull-down driving signal PD2 may be input to a gate electrode of the second transistor TR2. The first transistor TR1 and the second transistor TR2 may each be an N-type, but are not limited thereto. When the first pull-down driving signal PD1 and the second pull-down driving signal PD2 each have a turn-on level, the first transistor TR1 and the second transistor TR2 may be turned on, and the line to which the third supply voltage VSSQ is supplied and the first node N1 may be connected to each other.

According to the above-described embodiments, the first pull-up driver circuit 320 and the second pull-up driver circuit 330 are designed such that the first supply voltage VDDQ1 and the second supply voltage VDDQ2 are separately input, and thus, the entire decoupling capacitor may also be separately designed in the output driver 300 to have capacitance suitable for each of the first pull-up driver circuit 320 and the second pull-up driver circuit 330, and the capacitor optimization circuit 340 may also be designed. As a result, an on-chip PI may be robust in the PI-LTT without significantly changing an internal design structure of the output driver 300.

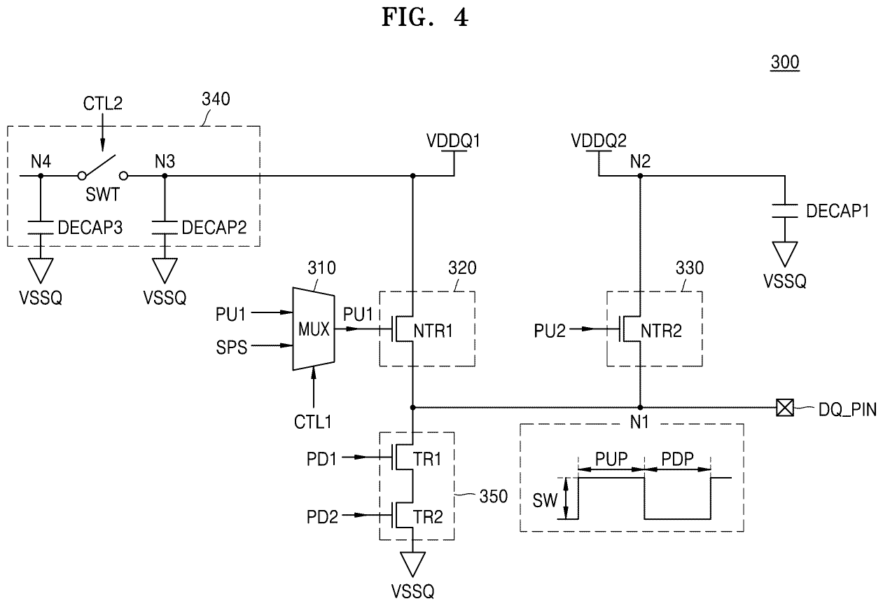

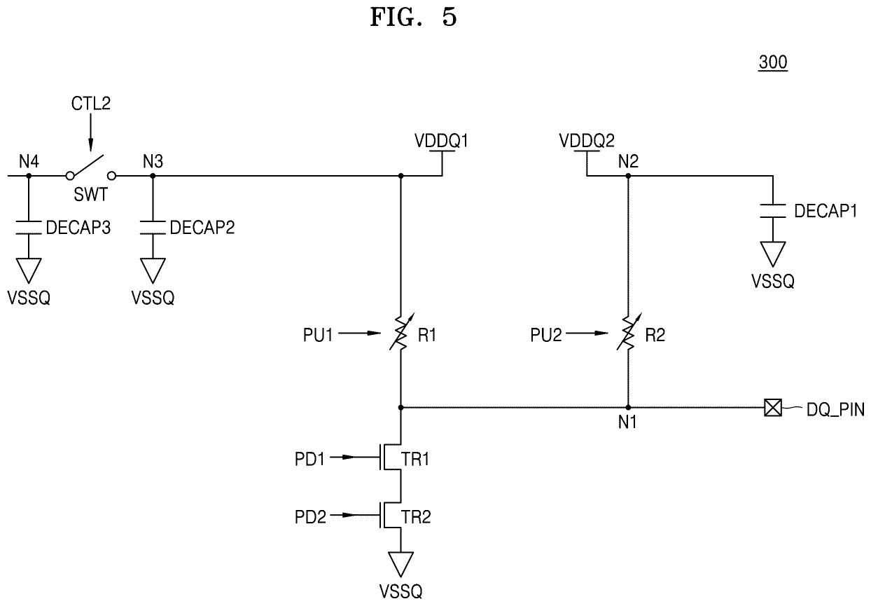

FIGS. 4 and 5 are diagrams for explaining first and second terminations of the output driver 300 of FIG. 3. Referring to FIGS. 4 and 5, in an embodiment, the first termination may be an LTT and the second termination may be a CTT. In the LTT or the CTT, a first level of the first supply voltage VDDQ1 and a second level of the second supply voltage VDDQ2 may each be 1.2 [V] as defined in the memory standard. Meanwhile, the selection circuit 310 may output the first pull-up driving signal PU1 to the first pull-up driver circuit 320. The first pull-up driver circuit 320 may connect the first node N1 to the third node N3 during a pull-up period PUP. The second pull-up driver circuit 330 may connect the first node N1 to the second node N2 during the pull-up period PUP. The switch SWT of the capacitor optimization circuit 340 may be turned off in response to a turn-off level of the second control signal CTL2, and the third node N3 and the fourth node N4 may be electrically open from each other. In this case, the second decoupling capacitor DECAP2 may assist a PI related to channel equalization in a PI-LTT while a pulse signal is input. The third decoupling capacitor DECAP3 may assist the PI with respect to an on-chip region. The second decoupling capacitor DECAP2 may be greater than or equal to a first capacitance.

Referring to FIG. 4, during the pull-up period PUP, the first pull-up driving signal PU1 and the second pull-up driving signal PU2 may each have a turn-on level, for example, a logic high level. The first pull-up driving signal PU1 and the second pull-up driving signal PU2 may each have a turn-off level, for example, a logic low level. In this case, the first N-type transistor NTR1 and the second N-type transistor NTR2 may be turned on, the first transistor TR1 and the second transistor TR2 may be turned off, and a level of a voltage applied to the first node N1 may increase. Accordingly, a data signal output through the data pin DQ_PIN may have an output high level (e.g., high-level output voltage (or voltage output high) (VOH) defined in the memory standard). Meanwhile, during a pull-down period PDP, the first pull-up driving signal PU1 and the second pull-up driving signal PU2 may each have a turn-off level, and the first pull-down driving signal PD1 and the second pull-down driving signal PD2 may each have a turn-on level. In this case, the first N-type transistor NTR1 and the second N-type transistor NTR2 may be turned off, the first transistor TR1 and the second transistor TR2 may be turned on, and the level of a voltage applied to the first node N1 may decrease. Accordingly, the data signal output through the data pin DQ PIN may have an output low level (e.g., low-level output voltage (or voltage output low) (VOL) defined in the memory standard). In this way, the data signal output through the data pin DQ PIN may be a periodic signal that swings between an output high level and an output low level. At this time, a swing width SW of the data signal and a center level between the output high level and the output low level may differ depending on the LTT or the CTT.

In an embodiment, the first capacitance may correspond to the size of an active region of a second pull-up driver, for example, the second N-type transistor NTR2. A second capacitance may correspond to the size of an active region of a first pull-up driver, for example, the first N-type transistor NTR1. For example, when the size of the active region of the first N-type transistor NTR1 is larger than the size of the active region of the second N-type transistor NTR2, the second capacitance of DECAP2 may be greater than the first capacitance of DECAP1. Alternatively, when the size of the active region of the first N-type transistor NTR1 is the same as the size of the active region of the second N-type transistor NTR2, the second capacitance may be equal to the first capacitance.

Referring to FIG. 5, in an embodiment, according to a resistance of each of a first resistor R1 and a second resistor R2 respectively corresponding to drain-to-source resistance of the first N-type transistor NTR1 and the second N-type transistor NTR2, the output driver 300 may operate as the LTT or as the CTT. For example, when the resistance of each of the first resistor R1 and the second resistor R2 is designed to be relatively large, the output driver 300 shown in FIGS. 4 and 5 may support the CTT; however, when the resistance of each of the first resistor R1 and the second resistor R2 is designed to be relatively small, the output driver 300 shown in FIGS. 4 and 5 may support the LTT.

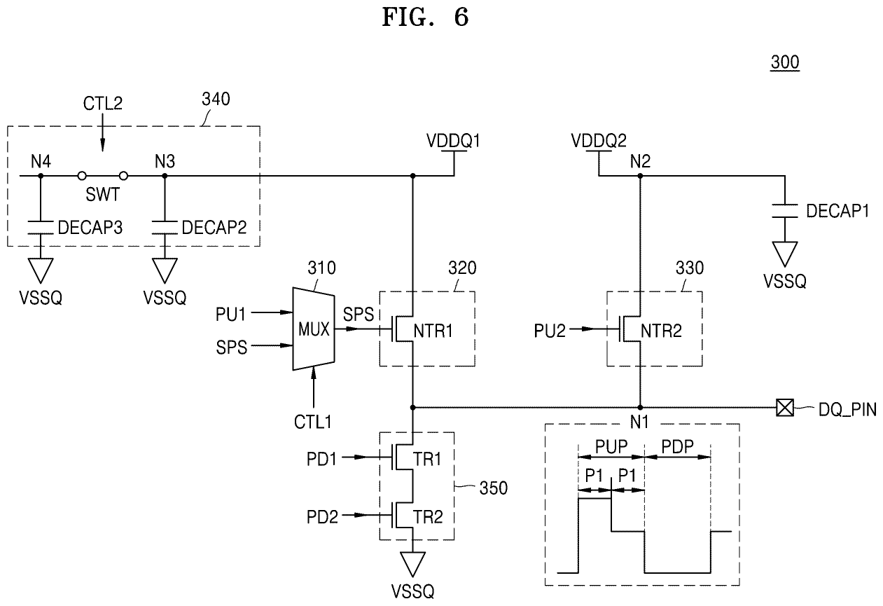

FIG. 6 is a diagram for explaining a third termination of the output driver 300 of FIG. 3. Referring to FIG. 6, in an embodiment, the third termination may be a PI-LTT. In the PI-LTT, according to the memory standard, a first level of the first supply voltage VDDQ1 may be 1.2 [V], and a second level of the second supply voltage VDDQ2 may be 0.6 [V]. The selection circuit 310 may output the pulse signal SPS to the first pull-up driver circuit 320. In the pull-up period PUP, the first pull-up driver circuit 320 may connect the first node N1 to the third node N3 during a first period P1 corresponding to a pulse width of the pulse signal SPS, and electrically open the first node N1 and the third node N3 during a second period P2 after the first period P1 has elapsed. The second pull-up driver circuit 330 may connect the first node N1 to the second node N2 during the pull-up period PUP. Meanwhile, the third node N3 and the fourth node N4 may be connected to each other by the turned-on switch SWT. The second decoupling capacitor DECAP2 and the third decoupling capacitor DECAP3 may be connected in parallel. At this time, a capacitance of the decoupling capacitor DECAP may be the sum of a second capacitance of DECAP2 and a third capacitance of DECAP3. The second decoupling capacitor DECAP2 may additionally assist a PI with respect to an on-chip region. That is, the second decoupling capacitor DECAP2 and the third decoupling capacitor DECAP3 connected in parallel may assist the PI with respect to the on-chip region.

Referring to FIG. 6, for example, during the pull-up period PUP, the second N-type transistor NTR2 may be turned on, the first transistor TR1 and the second transistor TR2 may be turned off, and a level of a voltage applied to the first node N1 may increase. Meanwhile, in the first period P1 of the pull-up period PUP, the first N-type transistor NTR1 may be turned on together with the second N-type transistor NTR2, and thus, the level of the voltage applied to the first node N1 during the first period P1 of the pull-up period PUP may significantly increase due to the combination of the first supply voltage VDDQ1 and the second supply voltage VDDQ2. As a result, a value of a resistance (e.g., Ron) defined in the memory standard may be maintained, and an impedance with respect to the data pin DQ_PIN may be properly matched.

Meanwhile, during the second period P2 of the pull-up period PUP, the first N-type transistor NTR1 may be turned off, unlike the second N-type transistor NTR2. Accordingly, the level of the voltage applied to the first node N1 during the second period P2 of the pull-up period PUP may decrease compared to the first period P1, but may be a high level. During the pull-down period PDP, the first N-type transistor NTR1 and the second N-type transistor NTR2 may be turned off, the first transistor TR1 and the second transistor TR2 may be turned on, and the level of a voltage applied to the first node N1 may decrease.

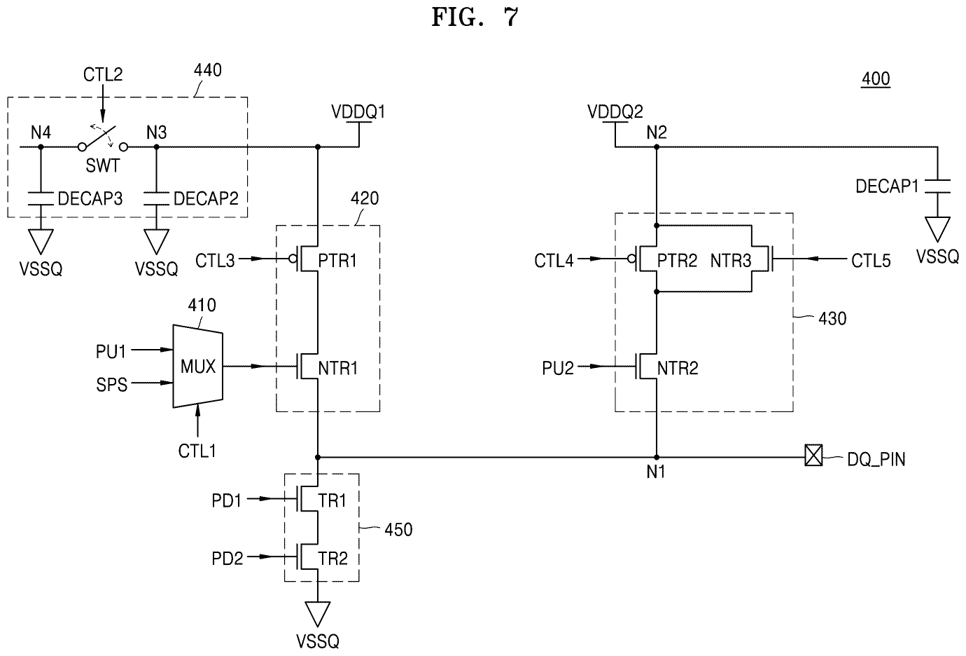

FIG. 7 is a circuit diagram of an output driver 400 according to an embodiment. Referring to FIG. 7, the output driver 400 may include a selection circuit 410, a first pull-up driver circuit 420, a second pull-up driver circuit 430, the first decoupling capacitor DECAP1, a capacitance optimization circuit 440, and a pull-down driver circuit 450. The selection circuit 410, the first decoupling capacitor DECAP1, the capacitance optimization circuit 440, and the pull-down driver circuit 450 may be the same as those described above.

In addition, the first pull-up driver circuit 420 may include the first N-type transistor NTR1 and a first P-type transistor PTR1. The first N-type transistor NTR1 is the same as described above with reference to FIGS. 3 to 6. The first P-type transistor PTR1 may “gate” the first supply voltage VDDQ1 based on a third control signal CTL3; the first P-type transistor PTR1 may include a first electrode, a second electrode, and a gate electrode. The first electrode of the first P-type transistor PTR1 may be connected to the third node N3, and the first supply voltage VDDQ1 may be applied to the first electrode of the first P-type transistor PTR1. The second electrode of the first P-type transistor PTR1 may be connected to a first electrode of the first N-type transistor NTR1. The third control signal CTL3 may be applied to the gate electrode of the first P-type transistor PTR1. The third control signal CTL3 may be generated and output by a control logic circuit. When the third control signal CTL3 has a turn-on level (for a PMOS device), the first P-type transistor PTR1 may be turned on, and the third node N3 and the first electrode of the first N-type transistor NTR1 may be connected to each other to support a pull-up function.

The second pull-up driver circuit 430 may include a second N-type transistor NTR2, a second P-type transistor PTR2, and a third N-type transistor NTR3. The second N-type transistor NTR2 is the same as described above with reference to FIGS. 3 to 6. The second P-type transistor PTR2 may gate the second supply voltage VDDQ2 based on a fourth control signal CTL4 in an LTT or a CTT. The second P-type transistor PTR2 may include a first electrode, a second electrode, and a gate electrode. The first electrode of the second P-type transistor PTR2 may be connected to the second node N2, and the second supply voltage VDDQ2 may be applied to the first electrode of the second P-type transistor PTR2. The second electrode of the second P-type transistor PTR2 may be connected to a first electrode of the second N-type transistor NTR2. The fourth control signal CTL4 may be input to the gate electrode of the second P-type transistor PTR2. In an embodiment, in a PI-LTT, the fourth control signal CTL4 may have a turn-off level.

The third N-type transistor NTR3 may “gate” the second supply voltage VDDQ2 based on a fifth control signal CTL5 in the PI-LTT. The third N-type transistor NTR3 may include a first electrode, a second electrode, and a gate electrode. The first electrode of the third N-type transistor NTR3 may be connected to the second node N2, and the second electrode of the third N-type transistor NTR3 may be connected to the first electrode of the second N-type transistor NTR2. The fifth control signal CTL5 may be input to the gate electrode of the third N-type transistor NTR3. In an embodiment, the fifth control signal CTL5 may have a turn-off level in the LTT and the CTT. According to the above-described embodiments, the power consumption of the output driver 400 may be controlled by implementing power gating.

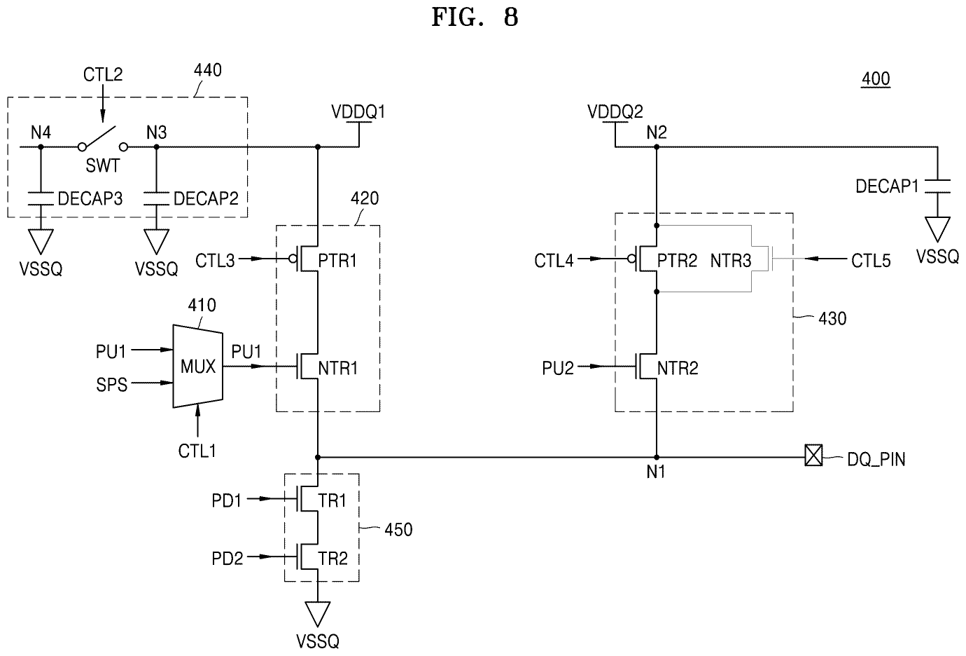

FIG. 8 is a diagram for explaining first and second terminations of the output driver 400 of FIG. 7. Referring to FIG. 8, the first termination according to an embodiment may be an LTT, and the second termination may be a CTT. In the LTT or the CTT, the first pull-up driving signal PU1 and the third control signal CTL3 may be input to the first pull-up driver circuit 420, and the second pull-up driving signal PU2, the fourth control signal CTL4, and the fifth control signal CTL5 may be input to the second pull-up driver circuit 430. At this time, the fifth control signal CTL5 may have a turn-off level. The first pull-down signal PD1 and the second pull-down signal PD2 may be input to the pull-down driver circuit 450. Meanwhile, the third node N3 and the fourth node N4 may be electrically opened by the turned-off switch SWT.

During the pull-up period PUP, the first pull-up driver circuit 420 may connect the first node N1 to the third node N3. The second pull-up driver circuit 430 may connect the first node N1 to the second node N2 during the pull-up period PUP. The pull-down circuit 450 may electrically open the first node N1 and a line to which the third supply voltage VSSQ is applied. During the pull-down period PDP, the pull-down circuit 450 may connect the first node N1 to the line to which the third supply voltage VSSQ is applied. The first pull-up driver circuit 420 and the second pull-up driver circuit 430 may each electrically open the first node N1, the second node N2, and the third node N3.

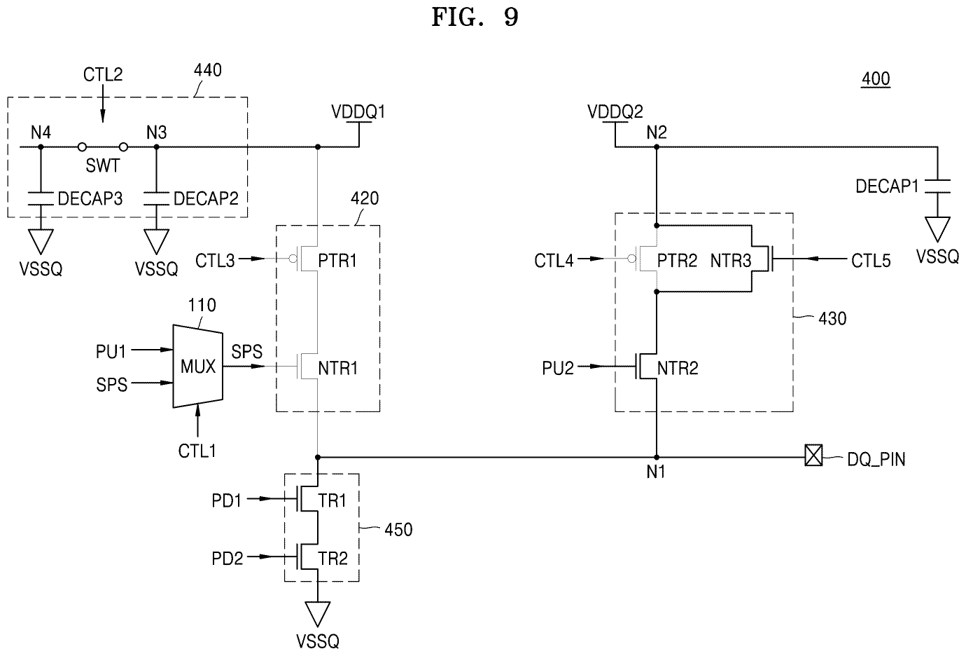

FIG. 9 is a diagram for explaining a third termination of the output driver 400 of FIG. 7. Referring to FIG. 9, the third termination according to an embodiment may be a PI-LTT. In the PI-LTT, the pulse signal SPS and the third control signal CTL3 may be input to the first pull-up driver circuit 420, and the second pull-up driving signal PU2, the fourth control signal CTL4, and the fifth control signal CTL5 may be input to the second pull-up driver circuit 430. At this time, the first N-type transistor NTR1 may be turned on only in a period in which the pulse signal SPS is input, and the fourth control signal CTL4 may have a turn-on level only while the pulse signal SPS is input. The fourth control signal CTL4 may have a turn-off level. The third node N3 and the fourth node N4 may be connected to each other by the turned-on switch SWT, and the second decoupling capacitor DECAP2 and the third decoupling capacitor DECAP3 may be connected in parallel.

During the first period P1 of the pull-up period PUP, the first pull-up driver circuit 420 may connect the first node N1 to the third node N3. The first period may be the period in which the pulse signal SPS is input. During the second period P2 after the first period P1 of the pull-up period PUP, the first pull-up driver circuit 420 may electrically open the first node N1 and the third node N3. During the pull-up period PUP, the second pull-up driver circuit 430 may connect the first node N1 to the second node N2, and the pull-down circuit 450 may electrically open the first node N1 and a line to which the third supply voltage VSSQ is applied. During the pull-down period PDP, the pull-down circuit 450 may connect the first node N1 to the line to which the third supply voltage VSSQ is applied. The first pull-up driver circuit 420 and the second pull-up driver circuit 430 may each electrically open the first node N1, the second node N2, and the third node N3.

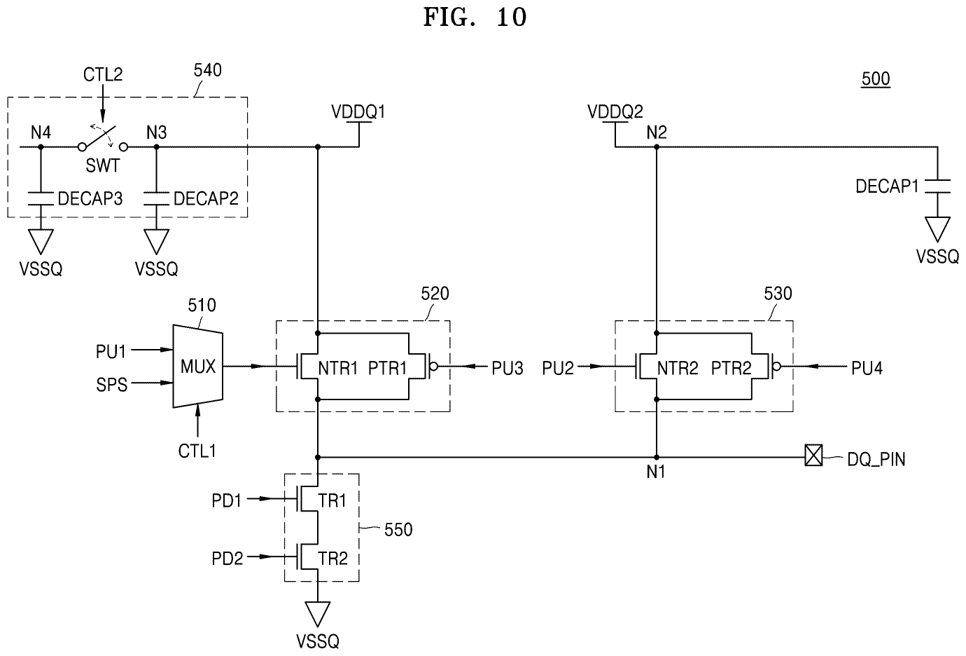

FIG. 10 is a circuit diagram of an output driver 500 according to an embodiment. Referring to FIG. 10, the output driver 500 may include a selection circuit 510, a first pull-up driver circuit 520, a second pull-up driver circuit 530, the first decoupling capacitor DECAP1, a capacitance optimization circuit 540, and a pull-down driver circuit 550. The output driver 500 may support all first to third terminations (e.g., an LTT, a CTT, and a PI-LTT). The selection circuit 510, the first decoupling capacitor DECAP1, the capacitance optimization circuit 540, and the pull-down driver circuit 550 may be the same as those described above.

The first pull-up driver circuit 520 may include the first N-type transistor NTR1 and the first P-type transistor PTR1. The first N-type transistor NTR1 is the same as described above with reference to FIGS. 3 to 6. The first P-type transistor PTR1 may include a first electrode, a second electrode, and a gate electrode. The first electrode of the first P-type transistor PTR1 may be connected to a first electrode of the first N-type transistor NTR1 and the third node N3. The second electrode of the first P-type transistor PTR1 may be connected to the first node N1. The third pull-up driving signal PU3 may be applied to the gate electrode of the first P-type transistor PTR1. In an embodiment, the first N-type transistor NTR1 may be a pull-up driver to support the LTT, and the first P-type transistor PTR1 may be a pull-up driver to support the CTT.

The second pull-up driver circuit 530 may include the second N-type transistor NTR2, and the second P-type transistor PTR2. The second N-type transistor NTR2 is the same as described above with reference to FIGS. 3 to 6. The second P-type transistor PTR2 may include a first electrode, a second electrode, and a gate electrode. The first electrode of the second P-type transistor PTR2 may be connected to the first electrode of the second N-type transistor NTR2 and the second node N2. The second electrode of the second P-type transistor PTR2 may be connected to the first node N1. The fourth pull-up driving signal PU4 may be applied to the gate electrode of the second P-type transistor PTR2. In an embodiment, the second N-type transistor NTR2 may be a pull-up driver to support the LTT, and the second P-type transistor PTR2 may be a pull-up driver to support the CTT.

According to the above-described embodiments, a plurality of terminations (e.g., the first to third terminations) may all be supported, thereby reducing the time and cost required to mass-produce a product matching the memory standard, and providing user convenience and high satisfaction.

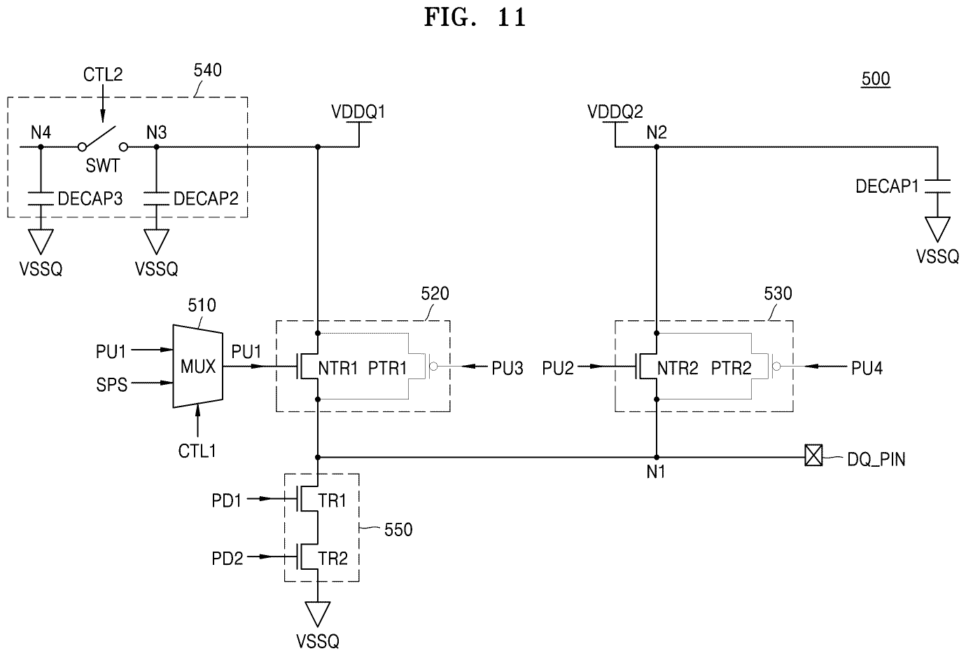

FIG. 11 is a diagram for explaining a first termination of the output driver 500 of FIG. 10. Referring to FIG. 11, the first termination according to an embodiment may be an LTT. In the LTT, the first pull-up driving signal PU1 and the third pull-up driving signal PU3 may be input to the first pull-up driver circuit 520, and the second pull-up driving signal PU2 and the fourth pull-up driving signal PU4 may be input to the second pull-up driver circuit 530. At this time, the third pull-up driving signal PU3 and the fourth pull-up driving signal PU4 may each have a turn-off level. The first pull-down signal PD1 and the second pull-down signal PD2 may be input to the pull-down driver circuit 550. Meanwhile, the third node N3 and the fourth node N4 may be electrically opened by the turned-off switch SWT.

During the pull-up period PUP, the first N-type transistor NTR1 may connect the first node N1 to the third node N3, and the second N-type transistor NTR2 may connect the first node N1 to the second node N2. The pull-down circuit 550 may electrically open the first node N1 and a line to which the third supply voltage VSSQ is applied. In contrast, during the pull-down period PDP, the pull-down circuit 550 may connect the first node N1 to the line to which the third supply voltage VSSQ is applied. The first N-type transistor NTR1 and the second N-type transistor NTR2 may each electrically open the first node N1, the second node N2, and the third node N3.

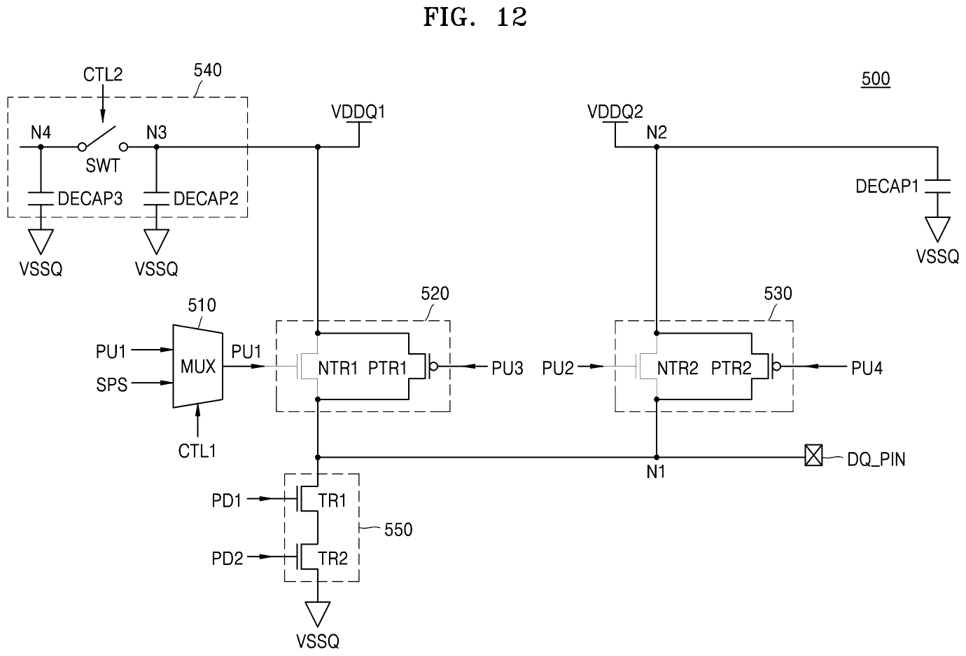

FIG. 12 is a diagram for explaining a second termination of the output driver 500 of FIG. 10. Referring to FIG. 12, the second termination according to an embodiment may be a CTT. In the CTT, the first pull-up driving signal PU1 and the third pull-up driving signal PU3 may be input to the first pull-up driver circuit 520, and the second pull-up driving signal PU2 and the fourth pull-up driving signal PU4 may be input to the second pull-up driver circuit 530. At this time, the second pull-up driving signal PU2 may have a turn-off level. The first pull-down driving signal PD1 and the second pull-down driving signal PD2 may be input to the pull-down driver circuit 550. Meanwhile, the third node N3 and the fourth node N4 may be electrically opened by the turned-off switch SWT.

During the pull-up period PUP, the first P-type transistor PTR1 may connect the first node N1 to the third node N3, and the second P-type transistor PTR2 may connect the first node N1 to the second node N2. The pull-down circuit 550 may electrically open the first node N1 and a line to which the third supply voltage VSSQ is applied. In contrast, during the pull-down period PDP, the pull-down circuit 550 may connect the first node N1 to the line to which the third supply voltage VSSQ is applied. The first P-type transistor PTR1 and the second P-type transistor PTR2 may each electrically open the first node N1, the second node N2, and the third node N3.

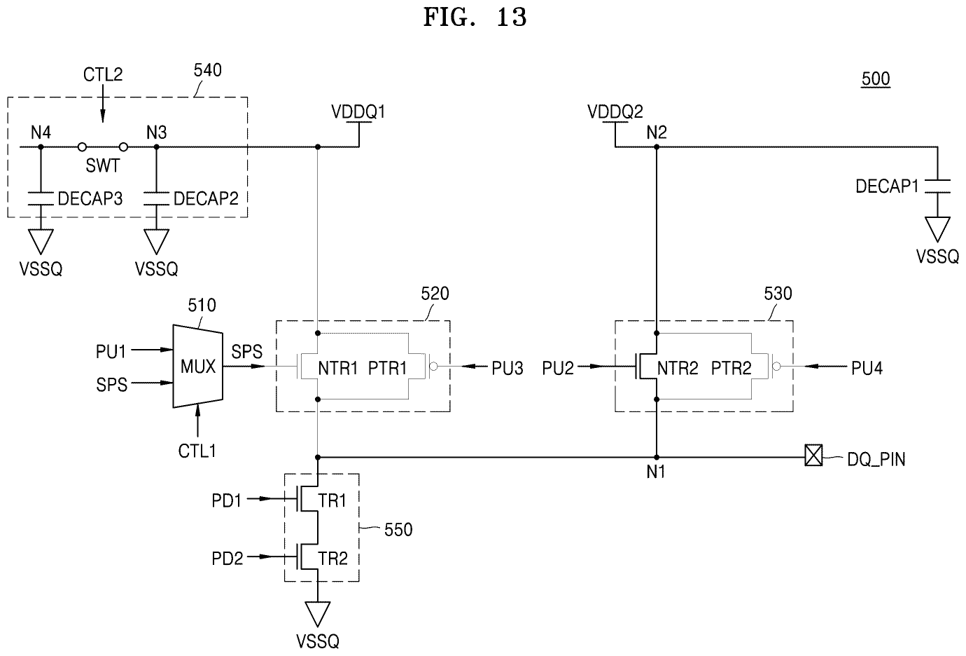

FIG. 13 is a diagram for explaining a third termination of the output driver 500 of FIG. 10. Referring to FIG. 13, the third termination according to an embodiment may be a PI-LTT. In the PI-LTT, the pulse signal SPS may be input to the first pull-up driver circuit 520, and the second pull-up driving signal PU2 and the fourth pull-up driving signal PU4 may be input to the second pull-up driver circuit 530. At this time, the first N-type transistor NTR1 may be turned on only in a period where the pulse signal SPS is input. The third pull-up driving signal PU3 and the fourth pull-up driving signal PU4 may each have a turn-off level. The second decoupling capacitor DECAP2 and the third decoupling capacitor DECAP3 may be connected in parallel by the turned-on switch SWT.

During the first period P1 of the pull-up period PUP, the first N-type transistor NTR1 may connect the first node N1 to the third node N3. During the second period P2 of the pull-up period PUP, the first N-type transistor NTR1 may electrically open the first node N1 and the third node N3. During the pull-up period PUP, the second N-type transistor NTR2 may connect the first node N1 to the second node N2, and the pull-down circuit 550 may electrically open the first node N1 and a line to which the third supply voltage VSSQ is applied. But, during the pull-down period PDP, the pull-down circuit 550 may connect the first node N1 to the line to which the third supply voltage VSSQ is applied. The first N-type transistor NTR1 and the second N-type transistor NTR2 may each electrically open the first node N1, the second node N2, and the third node N3.

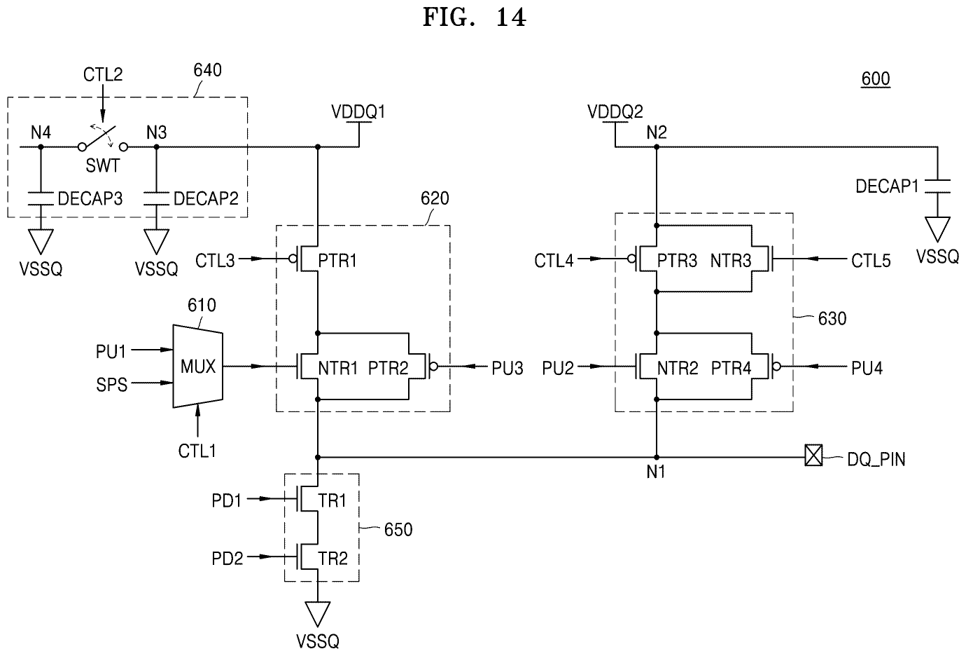

FIG. 14 is a circuit diagram of an output driver 600 according to an embodiment. Referring to FIG. 14, the output driver 600 may include a selection circuit 610, a first pull-up driver circuit 620, a second pull-up driver circuit 630, the first decoupling capacitor DECAP1, a capacitance optimization circuit 640, and a pull-down driver circuit 650. The output driver 600 may support all first to third terminations (e.g., an LTT, a CTT, and a PI-LTT). The selection circuit 610, the first decoupling capacitor DECAP1, the capacitance optimization circuit 640, and the pull-down driver circuit 650 may be the same as those described above.

The first pull-up driver circuit 620 may include the first N-type transistor NTR1, the first P-type transistor PTR1, and the second P-type transistor PTR2. The first N-type transistor NTR1 is the same as described above with reference to FIGS. 3 to 6. The first P-type transistor PTR1 is the same as described above with reference to FIGS. 7 to 9. The second P-type transistor PTR2 is the same as the first P-type transistor PTR1 described above with reference to FIGS. 10 to 13. The second pull-up driver circuit 630 may include the second N-type transistor NTR2, the third P-type transistor PTR3, the third N-type transistor NTR3, and a fourth P-type transistor PTR4. The second N-type transistor NTR2 is the same as described above with reference to FIGS. 3 to 6. The third P-type transistor PTR3 and the third N-type transistor NTR3 are respectively the same as the second P-type transistor PTR2 and the third N-type transistor NTR3 described above with reference to FIGS. 7 to 9. The fourth P-type transistor PTR4 is the same as the second P-type transistor PTR2 described above with reference to FIGS. 10 to 13. A transistor included in each of the first pull-up driver circuit 620 and the second pull-up driver circuit 630 may be referred to as a pull-up driver.

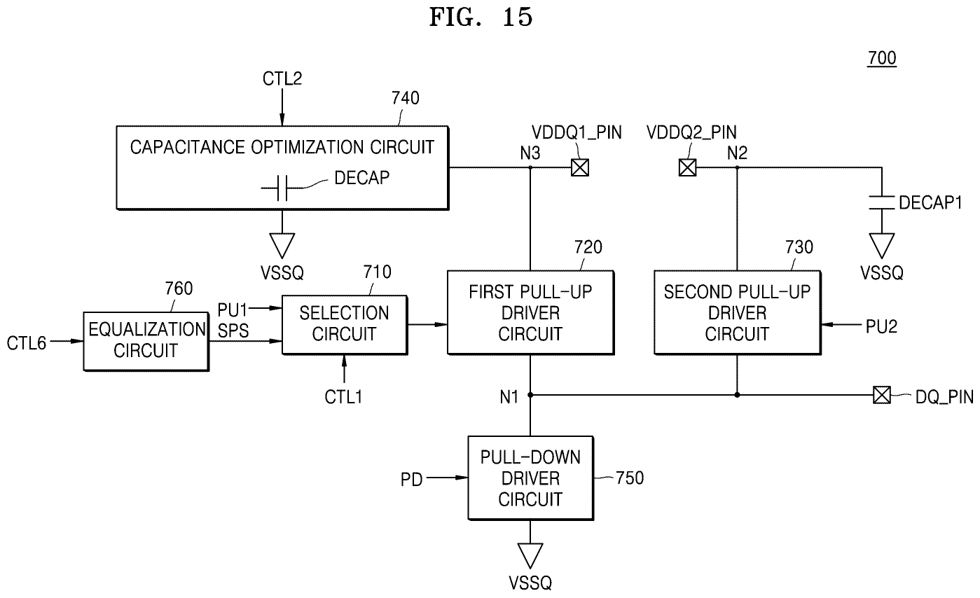

FIG. 15 is a diagram showing an output driver 700 according to an embodiment. Referring to FIG. 15, the output driver 700 may include a selection circuit 710, a first pull-up driver circuit 720, a second pull-up driver circuit 730, the first decoupling capacitor DECAP1, a capacitance optimization circuit 740, a pull-down driver circuit 750, and an equalization circuit 760. The selection circuit 710, the first pull-up driver circuit 720, the second pull-up driver circuit 730, the first decoupling capacitor DECAP1, the capacitance optimization circuit 740, and the pull-down driver circuit 750 are the same as described above with reference to FIG. 1.

The equalization circuit 760 may output the pulse signal SPS based on the third control signal CTL3 in order to offset the characteristics of a low-pass filter of a channel and amplify a high-frequency component of data output to the outside. The third control signal CTL3 may be generated and output by control logic. The equalization circuit 760 may be referred to as an equalizer. In an embodiment, the equalization circuit 760 may be implemented as a feed-forward equalizer (FFE). However, the equalization circuit 760 is not limited thereto, and in other embodiments, may also be implemented as an equalizer such as Decision Feedback Equalization (DFE), Continuous Time Linear Equalization (CTLE), etc. In an embodiment, the equalization circuit 760 may operate or stop operating as needed in a PI-LTT.

According to the above-described embodiment, separating power with respect to an equalization pass may result in providing an equalizer that is robust to an SI, optimizing a capacitance required by the output driver 700, and allocating an extra space and a capacitor secured by the output driver 700 as power to an on-chip region of a semiconductor chip including the output driver 700 according to an optimized capacitor. In addition, according to the above-described embodiment, equalization may be implemented while maintaining the resistance (e.g., Ron) of a pull-up driver at a value (e.g., 37.50) defined in the memory standard, and thus, the SI may be robust without increasing Cio and the chip size. Additionally, according to the above-described embodiment, equalization is implemented in the PI-LTT as a transistor included in the first pull-up driver circuit 720, and thus, the number of transistors required to implement equalization may be reduced, thereby reducing the size and the power consumption of the semiconductor chip.

FIG. 16 is a block diagram of an interface circuit 1 according to an embodiment. Referring to FIG. 16, the interface circuit 1 may communicate with the outside. The interface circuit 1 may include a pre-driver circuit 10 and an output driver circuit 11. The pre-driver circuit 10 may output a plurality of driving signals DSs based on internal data IDATA and a clock signal CLK. The internal data IDATA may be, for example, data stored in a plurality of memory cells. The clock signal CLK may be, for example, a data strobe signal. The plurality of driving signals DSs may include a pull-up driving signal and a pull-down driving signal.

The output driver circuit 11 may output data DATA based on the plurality of driving signals DSs and a plurality of control signals CTLs received from the outside. The data may be transmitted to the outside through the data pin DQ_PIN and a channel. As described above with reference to the embodiment shown in FIGS. 1 through 15, some embodiments of the inventive concept may be applied to the output driver circuit 11.

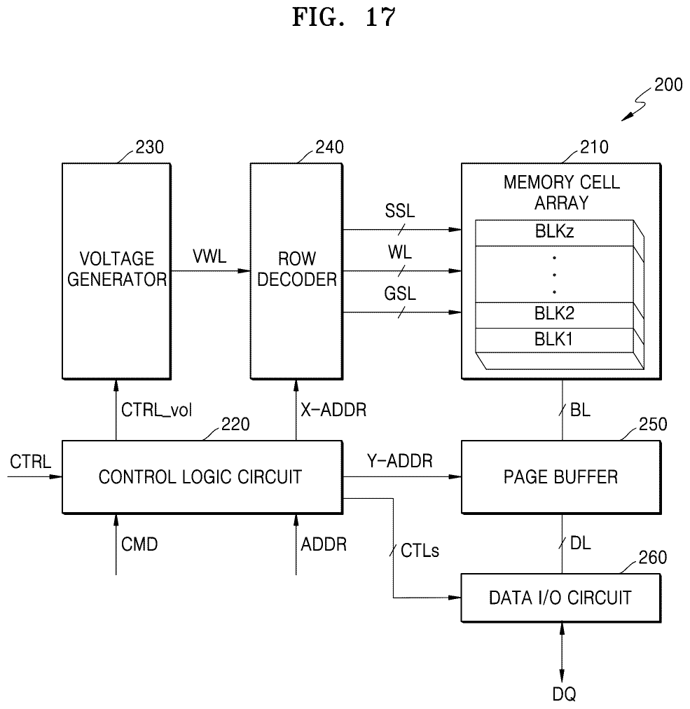

FIG. 17 is a diagram of a non-volatile memory 200, according to an embodiment. Referring to FIG. 17, the non-volatile memory 200 may include a memory cell array 211, a control logic 220, a voltage generator 230, a row decoder 240, and a page buffer circuit 250. In an optional or additional embodiment, the non-volatile memory 200 may include a data input/output (I/O) circuit and/or an I/O interface.

The memory cell array 211 may include a plurality of memory cells and be connected to word lines WL, string selection lines SSL, ground selection lines GSL, and a plurality of bit lines BL. For example, the memory cell array 211 may be connected to the row decoder 240 through word lines WL, string selection lines SSL, and ground selection lines GSL and be connected to the page buffer circuit 250 through the plurality of bit lines BL. The memory cell array 211 may include a plurality of memory blocks BLK1 to BLKz (hereinafter, “BLK” generally), where z is an integer greater than zero (0). For example, each memory block of the plurality of memory blocks BLK may have a three-dimensional (3D) structure (or a vertical structure). That is, each of memory blocks BLK may include structures extending in first to third directions. For example, each of memory blocks BLK may include a plurality of NAND strings extending in a third direction. In an embodiment, the plurality of NAND strings may be a predetermined distance apart from each other in the first and second directions. The plurality of memory blocks BLK may be selected by the row decoder 240. For example, the row decoder 240 may select a memory block corresponding to a block address out of the plurality of memory blocks BLK.

Each of the memory cells included in the memory cell array 211 may store at least one bit. For example, each of the memory cells may be an SLC configured to store one (1)-bit data. For another example, each of the memory cells may be an MLC configured to store two (2)-bit data. For yet another example, each of the memory cells may be a TLC configured to store three (3)-bit data. For yet another example, each of the memory cells may be a quad-level cell (or quadruple-level cell) (QLC) configured to store four (4)-bit data. However, the inventive concept is not limited in this regard. That is, the memory cells included in the memory cell array 211 may be configured to store more than four (4) bits of data.

The plurality of memory blocks BLK may include at least one of a single-level cell block including SLCs, a multi-level cell block including MLCs, a triple-level cell block including TLCs, and a quad-level cell block including QLCs. That is, from among the plurality of memory blocks BLK included in the memory cell array 211, some memory blocks may be SLC blocks, and other memory blocks may be MLC blocks, TLC blocks, and/or QLC blocks.

In an embodiment, the memory cell array 211 may be configured to place the plurality of memory cells into an erase state, when an erase voltage is applied to the memory cell array 211. Alternatively or additionally, the memory cell array 211 may be configured to place the plurality of memory cells into a program state, when a program voltage is applied to the memory cell array 211. In this case, each of the memory cells may have an erase state or at least one program state, according to a threshold voltage. That is, states of each of the memory cells may include the erase state and the at least one program state, and a predetermined state of each of the memory cells may be the erase state or a predetermined program state.

The control logic 220 may control various operations in the non-volatile memory 200. For example, the control logic 220 may write data to the memory cell array 211 and/or output various control signals for reading data from the memory cell array 211, based on a command CMD, an address ADDR, and a control signal CTRL.

The various control signals output from the control logic 220 may be provided to the voltage generator 230, the row decoder 240, and the page buffer circuit 250. The control logic 220 may provide a voltage control signal CTRL_vol to the voltage generator 230.

In some embodiments, the control logic 220 may further include a cell counter 221. The cell counter 221 may count the number of memory cells that fall within a predetermined threshold voltage range, from data sensed by the page buffer circuit 250. The cell counter 221 may generate a memory cell count value indicating the number of memory cells. In an embodiment, a memory cell that is counted may be referred to as an OFF cell. In an optional or additional embodiment, a memory cell that is counted may be referred to as an ON cell.

The voltage generator 230 may be electrically connected to the memory cell array 211 through a plurality of word lines WL. The voltage generator 230 may generate various voltages for performing a program operation, a read operation, and an erase operation on the memory cell array 211, based on the voltage control signal CTRL_vol. The voltage generator 230 may generate word line voltages VWL, for example, a program voltage, a verification voltage, a read voltage, and an erase voltage.

The program voltage, the verification voltage, the read voltage, and the erase voltage, which may be generated by the voltage generator 230, may be provided to a selected word line out of the plurality of word lines WL. The selected word line may be at least one word line selected by a row address X-ADDR. The selected word line may be referred to as a selection word line.

At the erase operation, the voltage generator 230 may apply the erase voltage to a well and/or a common source line of a memory block. Alternatively or additionally, the voltage generator 230 may apply an erase permission voltage (e.g., a ground voltage) to the word lines WL of the memory block or word lines WL corresponding to some sub-blocks, based on an erase address. At an erase verification operation, the voltage generator 230 may apply an erase verification voltage to the word lines WL of one memory block or apply the erase verification voltage by a unit of one word line.

During a program operation, the voltage generator 230 may apply a program voltage to the selection word line of the plurality of word lines WL and apply a program pass voltage to unselected word lines of the plurality of word lines WL. At a program verification operation, the voltage generator 230 may apply a program verification voltage to the selection word line and apply a verification pass voltage to the unselected word lines. During a normal read operation, the voltage generator 230 may apply a read voltage to the selection word line and apply a read pass voltage to the unselected word lines. During a data recovery read operation, the voltage generator 230 may apply a read pass voltage to the selection word line and apply a read voltage to at least one word line adjacent to the selection word line. Alternatively or additionally, the voltage generator 230 may apply a read voltage to the selection word line and apply a read voltage to at least one word line adjacent to the selection word line. A word line adjacent to the selection word line may be referred to as an adjacent word line.

The row decoder 240 may select a predetermined word line out of the word lines WL in response to a row address X-ADDR received from the control logic 220. For example, at the program operation, the row decoder 240 may provide a program voltage to the selected word line. Alternatively or additionally, the row decoder 240 may select some of the string selection lines SSL and/or some of the ground selection lines GSL in response to the row address X-ADDR received from the control logic 220.

The page buffer circuit 250 may be connected to the memory cell array 211 through the plurality of bit lines BL. The page buffer circuit 250 may select some bit lines out of the plurality of bit lines BL in response to a column address Y-ADDR received from the control logic 220. At a verification operation (e.g., the erase verification operation and/or the program verification operation) and/or the read operation, the page buffer circuit 250 may operate as a sense amplifier and sense data stored in the selected memory cell through the selected bit line. Moreover, at the program operation, the page buffer circuit 250 may operate as a write driver and input desired data in the memory cell array 211. The page buffer circuit 250 may include a plurality of page buffers. For example, each of the page buffers may be connected to at least one bit line.

The page buffer circuit 250 may store data read from the memory cell array 211 and/or store data to be stored in the memory cell array 211. The page buffer circuit 250 may include a plurality of page buffers respectively connected to the plurality of bit lines BL. The plurality of page buffers may be located to respectively correspond to the plurality of bit lines BL. Each of the page buffers may include a plurality of latches. Hereinafter, the page buffer circuit 250 may be defined as including the page buffer connected to each of the bit lines BL. However, in some embodiments, terms may be defined differently. For example, one page buffer may be provided to correspond to a plurality of bit lines BL, and a unit of component arranged to correspond to each bit line BL may be defined as a page buffer unit. In an embodiment, the control logic 220, the voltage generator 230, the row decoder 240, and the page buffer circuit 250 may be included in a peripheral circuit.

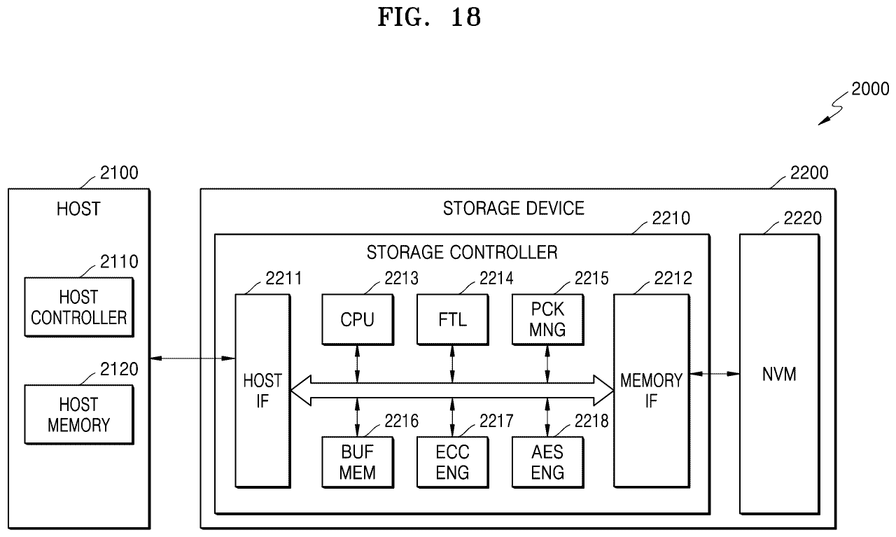

FIG. 18 is a block diagram of a storage system 2000, according to an embodiment. Referring to FIG. 18, the storage system 2000 may include a host 2100 and a storage device 2200. In an embodiment, the storage device 2200 may include a storage controller 2210 and a non-volatile memory (e.g., NVM 2220). In an optional or additional embodiment, the host 2100 may include a host controller 2110 and a host memory 2120. The host memory 2120 may serve as a buffer memory configured to temporarily store data to be transmitted to the storage device 2200 and/or data transmitted from the storage device 2200.

The storage device 2200 may include storage media configured to store data in response to requests from the host 2100. For example, the storage device 2200 may include at least one of an SSD, an embedded memory, and a detachable external memory. When the storage device 2200 is the SSD, the storage device 2200 may be a device that conforms to an NVMe standard, for example. Alternatively or additionally, when the storage device 2200 is an embedded memory or an external memory, the storage device 2200 may be a device that conforms to a UFS standard or an eMMC standard. Each of the host 2100 and the storage device 2200 may generate a packet according to an adopted standard protocol and transmit the packet.

When the NVM 2220 of the storage device 2200 may include a flash memory, the flash memory may include a 2D NAND memory array or a 3D (or vertical) NAND (VNAND) memory array. Alternatively or additionally, the storage device 2200 may include various other types of non-volatile memories. For example, the storage device 2200 may include, but not be limited to, MRAM, spin-transfer torque MRAM (STT-MRAM), conductive bridging RAM (CBRAM), ferroelectric RAM (FRAM), PRAM, and RRAM.

According to an embodiment, the host controller 2110 and the host memory 2120 may be implemented as separate semiconductor chips. Alternatively or additionally, in some embodiments, the host controller 2110 and the host memory 2120 may be integrated into the same semiconductor chip. For example, the host controller 2110 may include any one of a plurality of modules included in an application processor. For another example, the application processor may be implemented as a System on Chip (SoC). Alternatively or additionally, the host memory 2120 may be an embedded memory included in the application processor or a non-volatile memory or a memory module, which may be outside the application processor.

The host controller 2110 may manage an operation of storing data (e.g., write data) of a buffer region of the host memory 2120 in the non-volatile memory 2220 and/or storing data (e.g., read data) of the non-volatile memory 2220 in the buffer region.

The storage controller 2210 may include a host interface 2211, a memory interface 2212, and a CPU 2213. In an embodiment, the storage controller 2210 may further include a flash translation layer (FTL) 2214, a packet manager 2215, a buffer memory 2216, an ECC engine 2217, and an advanced encryption standard (AES) engine 2218. The storage controller 2210 may further include a working memory (not shown) in which the FTL 2214 is loaded. The CPU 2213 may execute the FTL 2214 to control write and read operations on the NVM 2220.

The host interface 2211 may transmit and/or receive packets to and/or from the host 2100. A packet transmitted from the host 2100 to the host interface 2211 may include a command and/or data to be written the non-volatile memory 2220. A packet transmitted from the host interface 2211 to the host 2100 may include a response to the command and/or data read from the non-volatile memory 2220. The memory interface 2212 may transmit data to be written to the non-volatile memory 2220 and/or receive data read from the non-volatile memory 2220. The memory interface 2212 may be configured to comply with one or more standard protocols, such as, but not limited to, Toggle and/or open NAND flash interface (ONFI).

The FTL 2214 may perform various functions, such as, but not limited to, an address mapping operation, a wear-leveling operation, and a garbage collection operation. The address mapping operation may refer to an operation of converting a logical address received from the host 2100 into a physical address used to physically store data in the non-volatile memory 2220. The wear-leveling operation may refer to a technique for preventing excessive deterioration of a specific block by allowing blocks of the non-volatile memory 2220 to be uniformly used. For example, the wear-leveling operation may be implemented using a firmware technique that balances erase counts of physical blocks. The garbage collection operation may refer to a technique for ensuring usable capacity in the non-volatile memory 2220 by erasing an existing block after copying valid data of the existing block to a new block.

The packet manager 2215 may generate a packet according to a protocol of an interface, which interfaces with the host 2100, and/or parse various types of information from the packet received from the host 2100. Alternatively or additionally, the buffer memory 2216 may temporarily store data to be written to the NVM 2220 and/or data to be read from the NVM 2220. Although, in some embodiments, the buffer memory 2216 may be a component included in the storage controllers 2210, the buffer memory 2216 may be outside the storage controllers 2210.

The ECC engine 2217 may perform error detection and correction operations on read data read from the NVM 2220. For example, the ECC engine 2217 may generate parity bits for write data to be written to the NVM 2220, and the generated parity bits may be stored in the NVM 2220 together with write data. During the reading of data from the NVM 2220, the ECC engine 2217 may correct an error in the read data by using the parity bits read from the NVM 2220 along with the read data, and output error-corrected read data. The AES engine 2218 may perform, by using a symmetric-key algorithm, at least one of an encryption operation and a decryption operation on data input to the storage controllers 2210.

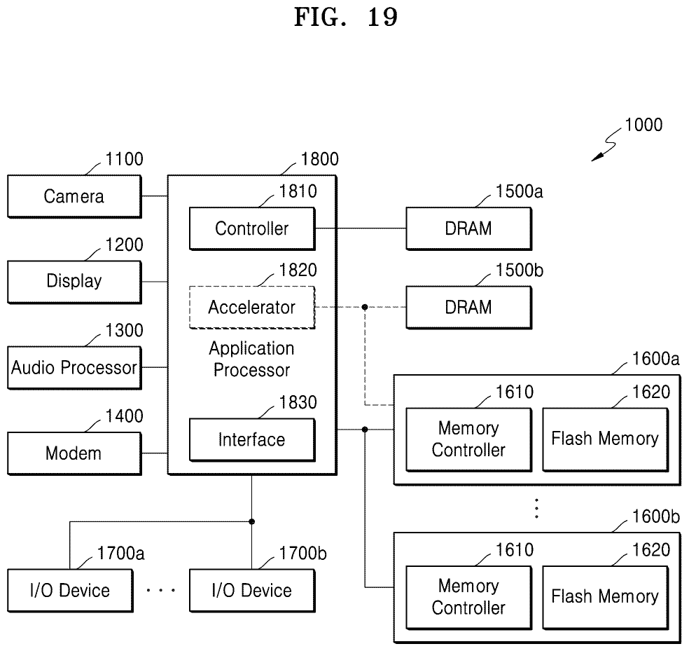

FIG. 19 is a block diagram illustrating at least a portion of an electronic system according to embodiments. Referring to FIG. 19, an electronic system 1000 may be implemented as, but not limited to, a laptop computer, a mobile phone, a smartphone, a tablet personal computer, a wearable device, a healthcare device, or an Internet of Things (IoT) device. In addition, the electronic system 1000 may be implemented as a server or a personal computer. The electronic system 1000 may include a camera 1100, a display 1200, an audio processor 1300, a modem 1400, volatile memories 1500a and 1500b, flash memories 1600a and 1600b, I/O devices 1700a and 1700b, and an application processor (AP) 1800 (hereinafter referred to as “AP”). The camera 1100 may capture a still image or a moving image according to a user's control. The audio processor 1300 may process audio data included in content stored in one or more of the flash memory devices 1600a and 1600b or provided from a network. The modem 1400 may be configured to modulate and transmit a signal to transmit/receive wired/wireless data, and may demodulate the modulated signal to restore the original signal at the receiving end. The I/O devices 1700a and 1700b may include devices that provide digital input and/or output functionality. The AP 1800 may control all or some operations of the electronic system 1000. The AP 1800 may control the display 1200 to display a portion of content. When a user input is received through the I/O devices 1700a and 1700b, the AP 1800 may perform a control operation corresponding to the user input. The AP 1800 may optionally include an accelerator 1820, which is a dedicated circuit for Artificial Intelligence (AI) data calculation. The volatile memory 1500b may additionally reside in the accelerator 1820. The accelerator 1820 may be a functional block that performs a certain function of the AP 1800. The accelerator 1820 may include a graphics processing unit (GPU), a neural processing unit (NPU), and a data processing unit (DPU). The GPU may be a block that specializes in processing graphics data. The NPU may be a block for professionally performing AI calculations and inference. The DPU may be a block specializing in data transmission.

The AP 1800 may control the volatile memories 1500a and 1500b through commands and mode register settings (e.g., MRS) conforming to the JEDEC (Joint Electron Device Engineering Council) standard. Alternatively, the AP 1800 may set a DRAM interface protocol to use a company-specific function, such as low voltage/high speed/reliability and a Cyclic Redundancy Check (CRC)/Error Correction Code (ECC) function. A controller 1810 included in the AP 1800 may correspond to the memory controller 110 described above with reference to FIG. 1.

The volatile memories 1500a and 1500b, which may comprise DRAM, may have relatively smaller latency and bandwidth than the I/O devices 1700a and 1700b or the flash memories 1600a and 1600b. The volatile memories 1500a and 1500b may be initialized at the power-on time point of the electronic system 1000, and may be used as a temporary storage location for the operating system and application data loaded with the operating system and application data, or may be used as an execution space for various software code. In the volatile memories 1500a and 1500b, addition/subtraction/multiplication/division operations, vector operations, address operations, or Fast Fourier Transform (FFT) operations may be performed. In addition, a function used for inference may be performed by the volatile memories 1500a and 1500b. Each of the volatile memories 1500a and 1500b may correspond to the memory device 120 described above with reference to FIG. 1.

The flash memories 1600a and 1600b may store pictures taken through the camera 1100 or data transmitted through a data network. Each of the flash memories 1600a, 1600b may include a memory controller 1610 and a flash memory array 1620; one or more operations of the flash memory array 1620 may be controlled by the memory controller 1610. The flash memories 1600a and 1600b may have a larger capacity than the volatile memories 1500a and 1500b.

While the inventive concept has been particularly shown and described with reference to embodiments thereof, it will be understood that various changes in form and details may be made therein without departing from the spirit and scope of the following claims.

1. An output driver, comprising:
a selection circuit configured to selectively output either a first pull-up driving signal or a pulse signal, in response to a received first control signal;
a first pull-up driver circuit configured to provide a first supply voltage to a first node electrically connected to a data pin, in response to the first pull-up driving signal or the pulse signal received from the selection circuit;
a second pull-up driver circuit configured to provide a second supply voltage having a second level, which is less than or equal to a first level of the first supply voltage, to the first node, in response to a second pull-up driving signal;
a first decoupling capacitor having a first terminal electrically connected to a second node to which the second supply voltage is applied and a second terminal electrically connected to a line to which a third supply voltage is applied, said third supply voltage having a third level less than the first and second levels;
a capacitance optimization circuit configured to change a capacitance of a decoupling capacitor having a first terminal electrically connected to a third node to which the first supply voltage is applied, in response to a received second control signal; and
a pull-down driver circuit configured to provide the third supply voltage to the first node, in response to a pull-down driving signal.

2. The output driver of claim 1, wherein the capacitance optimization circuit includes:
a second decoupling capacitor electrically connected between the third node and the line;
a third decoupling capacitor electrically connected between a fourth node, which is electrically connected to a logic circuit, and the line; and
a switch configured to electrically connect the third node to the fourth node based on the second control signal.

3. The output driver of claim 2, wherein a capacitance of the first decoupling capacitor corresponds to a size of the second pull-up driver circuit, and a capacitance of the second decoupling capacitor corresponds to a size of the first pull-up driver circuit.

4. The output driver of claim 1, wherein the first pull-up driver circuit includes a first N-type transistor having a first electrode to which the first supply voltage is applied, a second electrode electrically connected to the first node, and a gate electrode to which the first pull-up driving signal and the pulse signal are selectively applied one-at-a-time.

5. (canceled)

6. The output driver of claim 4, wherein the first pull-up driver circuit further includes a second P-type transistor including a first electrode electrically connected to the first electrode of the first N-type transistor, a second electrode electrically connected to the first node, and a gate electrode to which a third pull-up driving signal is applied.

7. The output driver of claim 1, wherein the second pull-up driver circuit includes a second N-type transistor including a first electrode to which the second supply voltage is applied, a second electrode electrically connected to the first node, and a gate electrode to which the second pull-up driving signal is applied.

8. (canceled)

9. The output driver of claim 7, wherein the second pull-up driver circuit further includes a fourth P-type transistor including a first electrode electrically connected to the first electrode of the second N-type transistor, a second electrode electrically connected to the first node, and a gate electrode to which a fourth pull-up driving signal is applied.

10. The output driver of claim 1,
wherein the selection circuit is configured to output the first pull-up driving signal to the first pull-up driver circuit;
wherein the first pull-up driver circuit is configured to electrically connect the first node to the third node during a pull-up period;
wherein the second pull-up driver circuit is configured to electrically connect the first node to the second node during the pull-up period; and
wherein the second level is equal to the first level.

11. The output driver of claim 1,
wherein the selection circuit is configured to output the pulse signal to the first pull-up driver circuit;
wherein the first pull-up driver circuit is configured to, in a pull-up period, electrically connect the first node to the third node during a first period corresponding to a pulse width of the pulse signal, and electrically open the first node and the third node during a second period after the first period has elapsed;
wherein the second pull-up driver circuit is configured to electrically connect the first node to the second node during the pull-up period;
wherein the second level is lower than the first level; and
wherein the first capacitance is less than a capacitance of the decoupling capacitor.

12. A non-volatile memory device, comprising:
a memory cell array having a plurality of memory cells therein;
a control logic circuit configured to output a plurality of control signals in response to a command signal; and
a data input/output circuit configured to generate a plurality of driving signals based on internal data and a clock signal output from the memory cell array, and output data based on the plurality of control signals and the plurality of driving signals, said data input/output circuit comprising:
a multiplexer configured to output either a received first pull-up driving signal or a received pulse signal, according to a first control signal;
a first pull-up driver including a first electrode electrically connected to a third node to which a first supply voltage is applied, a second electrode electrically connected to a first node connected to a data pin, and a gate electrode to which the first pull-up driving signal and the pulse signal are selectively applied one-at-a-time;
a second pull-up driver including a first electrode electrically connected to a second node to which a second supply voltage having a second level lower than the first level of the first supply voltage is applied, a second electrode electrically connected to the first node, and a gate electrode to which a second pull-up driving signal is applied;
a first decoupling capacitor having first capacitance electrically connected to a line to which a third supply voltage of a third level lower than the first level and the second level is applied, and the second node;
a second decoupling capacitor electrically connected to the third node and the line, said second decoupling capacitor having a second capacitance that is greater than or equal to the first capacitance;
a third decoupling capacitor having a third capacitance electrically connected to a fourth node and the line;
a switch configured to selectively connect the third node to the fourth node or electrically open the third node from the fourth node according to a second control signal;
a pull-down driver including a first electrode connected to the first node, a second electrode connected to the line, and a gate electrode to which a pull-down driving signal is applied; and
an equalizer configured to output the pulse signal based on a sixth control signal.

13. The non-volatile memory device of claim 12, wherein when the multiplexer selectively outputs the first pull-up driving signal:
the first pull-up driver is configured to electrically connect the first node to the third node during a pull-up period;
the second pull-up driver is configured to electrically connect the first node to the second node during the pull-up period; and
the switch is configured to electrically open the third node from the fourth node.

14. The non-volatile memory device of claim 12, wherein when the multiplexer selectively outputs the pulse signal:
the first pull-up driver is configured to, in a pull-up period, electrically connect the first node to the third node during a first period corresponding to a pulse width of the pulse signal, and electrically open the first node from the third node during a second period after the first period has elapsed;
the second pull-up driver is configured to electrically connect the first node to the second node during the pull-up period; and
the switch is configured to electrically connect the third node to the fourth node.

15. The non-volatile memory device of claim 12, wherein the data input/output circuit further includes:
a third pull-up driver including a first electrode electrically connected to the first electrode of the first pull-up driver, a second electrode electrically connected to the first node, and a gate electrode to which a third pull-up driving signal is applied, and having a type different from a type of the first pull-up driver; and
a fourth pull-up driver including a first electrode electrically connected to the first electrode of the second pull-up driver, a second electrode electrically connected to the first node, and a gate electrode to which a fourth pull-up driving signal is applied, and having a type that is same as the type of the third pull-up driver; and
wherein the type of the first pull-up driver is same as a type of the second pull-up driver.

16. (canceled)

17. (canceled)

18. The non-volatile memory device of claim 12, wherein the first capacitance corresponds to a size of an active region of the second pull-up driver, and the second capacitance corresponds to a size of an active region of the first pull-up driver.

19. A memory controller, comprising:
a processor configured to receive data and a command signal from external the memory controller, output a plurality of control signals based on the command signal, and output a clock signal and the data; and
a memory interface circuit configured to generate a plurality of driving signals based on the data and the clock signal, and output internal data based on the plurality of control signals and the plurality of driving signals, said memory interface circuit comprising:
a multiplexer configured to output either a first pull-up driving signal or a pulse signal according to a first control signal;
a first pull-up driver including a first electrode electrically connected to a third node to which a first supply voltage is applied, a second electrode electrically connected to a first node connected to a data pin, and a gate electrode to which the first pull-up driving signal and the pulse signal are selectively applied one-at-a-time;
a second pull-up driver including a first electrode electrically connected to a second node to which a second supply voltage having a second level lower than the first level of the first supply voltage is applied, a second electrode electrically connected to the first node, and a gate electrode to which a second pull-up driving signal is applied;
a first decoupling capacitor electrically connected to a line to which a third supply voltage of a third level lower than the first level and the second level is applied and the second node, and having a first capacitance;
a second decoupling capacitor electrically connected to the third node and the line and having a second capacitance greater than or equal to the first capacitance;
a third decoupling capacitor electrically connected to a fourth node and the line and having a third capacitance;
a switch configured to connect the third node to the fourth node or electrically open the third node from the fourth node according to a second control signal;
a pull-down driver including a first electrode electrically connected to the first node, a second electrode electrically connected to the line, and a gate electrode to which a pull-down driving signal is applied; and
an equalizer configured to output the pulse signal based on a sixth control signal.

20. The memory controller of claim 19,
wherein the multiplexer is configured to output the first pull-up driving signal;
wherein the first pull-up driver is configured to electrically connect the first node to the third node during a pull-up period;
wherein the second pull-up driver is configured to electrically connect the first node to the second node during the pull-up period; and
wherein the switch is configured to electrically open the third node from the fourth node.

21. The memory controller of claim 19,
wherein the multiplexer is configured to output the pulse signal;
wherein the first pull-up driver is configured to, during a pull-up period, electrically connect the first node to the third node during a first period corresponding to a pulse width of the pulse signal, and electrically open the first node from the third node during a second period after the first period has elapsed;
wherein the second pull-up driver is configured to electrically connect the first node to the second node during the pull-up period; and
wherein the switch is configured to connect the third node to the fourth node.

22. The memory controller of claim 19, wherein the memory interface circuit further includes:
a third pull-up driver including a first electrode electrically connected to the first electrode of the first pull-up driver, a second electrode electrically connected to the first node, and a gate electrode to which a third pull-up driving signal is applied, and having a type different from a type of the first pull-up driver; and
a fourth pull-up driver including a first electrode electrically connected to the first electrode of the second pull-up driver, a second electrode electrically connected to the first node, and a gate electrode to which a fourth pull-up driving signal is applied, and having a type that is same as the type of the third pull-up driver; and
wherein the type of the first pull-up driver is the same as a type of the second pull-up driver.

23. The memory controller of claim 19, wherein the memory interface circuit further includes:
a fifth pull-up driver including a first electrode electrically connected to the third node, a second electrode electrically connected to the first electrode of the first pull-up driver, and a gate electrode to which a third control signal is applied;
a sixth pull-up driver including a first electrode electrically connected to the second node, a second electrode electrically connected to the first electrode of the second pull-up driver, and a gate electrode to which a fourth control signal is applied, and having a type that is same as a type of the fifth pull-up driver; and
a seventh pull-up driver including a first electrode electrically connected to the second node, a second electrode electrically connected to the first electrode of the second pull-up driver, and a gate electrode to which a fifth control signal is applied, and having a type different from the type of the sixth pull-up driver.

24. The memory controller of claim 23, wherein the first capacitance corresponds to a size of an active region of the second pull-up driver, and the second capacitance corresponds to a size of an active region of the first pull-up driver.

25.-30. (canceled)
